(19) United States
(12) Patent Application Publication
(10) Pub. No.: US 2011/0220289 A1
(43) Pub. Date: Sep. 15, 2011

(54) MEMBER FOR PLASMA TREATMENT APPARATUS AND PRODUCTION METHOD THEREOF

(75) Inventors: Toshiyuki Tanaka, Mie (JP); Jun Hisamoto, Hyogo (JP); Hiroto Sugano, Mie (JP)

(73) Assignee: Kabushiki Kaisha Kobe Seiko Sho (Kobe Steel, Ltd.), Kobe-shi, Hyogo (JP)

(21) Appl. No.: 13/129,302

(22) PCT Filed: Dec. 2, 2008
(86) PCT No.: PCT/JP2008/071875

§ 371 Date: May 13, 2011

(51) Int. Cl. C23C 16/50; H01L 21/3065; C25D 11/02

(52) U.S. Cl. 156/345.43; 118/723 MW; 205/106

(57) ABSTRACT

A member for a plasma treatment apparatus is provided, which has excellent anti-sticking properties, is suitable, for example, as a lower electrode in CVD apparatuses, has a stable shape as the lower electrode, and can suppress abnormal discharge during plasma treatment. The member for a plasma treatment apparatus comprises a base material formed of an aluminum alloy having a smoothly machined surface and a treated anodic oxide coating provided on the surface of the base material and formed by hydrating an anodic oxide coating formed on the surface of the base material to form microcracks therein. The anodic oxide coating has a leak current density of more than 0.9×10⁻⁵ A/cm² at an applied voltage of 100 V, a thickness of not less than 3 μm, an arithmetic average surface roughness of less than 1 μm, and a dissolution rate of less than 100 mg/dm²/15 min in a phosphoric and chromic acid immersion test. The flatness of the surface on which the anodic oxide coating has been formed is not more than 50 μm.

### TECHNICAL FIELD

The present invention relates to a member for constituting a plasma treatment apparatus which performs, for example, film deposition or etching for the production of semiconductor devices and liquid crystal display devices.

### BACKGROUND ART

Various aluminum members are used as members for constituting plasma treatment apparatuses which perform, for example, film deposition or etching for the production of semiconductor devices and liquid crystal display devices. Typically, examples of such aluminum members include an upper electrode and a lower electrode to be arranged in an upper part and a lower part, respectively, in a process chamber of chemical vapor deposition (CVD) apparatuses working as film deposition apparatuses. Members constituting these electrodes require high corrosion resistance typically against a source gas and should have suitable surface shapes, because the surface shapes of the electrodes significantly affect the uniformity and stability of the process. Thus, various attempts have been made to control the surface shapes.

Among such members, the surface shape of the lower electrode of CVD apparatuses significantly affects film deposition, because the film deposition is performed while a workpiece such as a wafer or glass substrate is directly mounted on the lower electrode. In film deposition, “sticking” may occur in which the workpiece is attached to the lower electrode and is resistant to detachment, due to electrostatic adsorption. The sticking may cause the failure of the workpiece or a workpiece-supporting member of the CVD apparatus during the transportation of the workpiece from the lower electrode after the film deposition. To avoid this and to prevent sticking (to provide anti-sticking properties), the surface of the lower electrode is subjected to blasting (roughening) or another treatment to reduce the contact area with the workpiece.

The blasted lower electrode, however, has steep protrusions formed through blasting. The protrusions are worn by the contact with the workpiece to form dust to thereby cause contamination. Additionally, the wearing causes the lower electrode to change in its surface shape, this changes the thermal conduction from the lower electrode to the workpiece, namely, changes the film deposition conditions to thereby adversely affect the deposited film. To avoid these problems, Patent Literature (PTL) 1 discloses a technique for removing steep protrusions while maintaining surface roughness, by performing grinding after blasting. PTL 2 discloses a technique for reducing the contact area with the workpiece by forming patterned depressions and protrusions typically of wavy shapes on the surface of the lower electrode.
PTL1: Japanese Patent No. 3160229 (Paragraphs 0008 to 0010, 0021, 0025, and FIG. 2)
PTL2: Japanese Unexamined Patent Application Publication (JP-A) No. H08(1996)-70034 (claim 5, Paragraph 0016, and FIG. 10)

### DISCLOSURE OF INVENTION

### Technical Problem

However, a lower electrode after blasting as in PTL 1 may suffer warping due to inevitable residual stress, and this may impede the lower electrode to support the workpiece stably. A lower electrode having patterned depressions and protrusions on its surface as in PTL 2 may suffer unevenness along the pattern in film deposition of the workpiece. Specifically, the known techniques fail to provide a member having satisfactory performance as a lower electrode while having good anti-sticking properties.

When a member for a plasma treatment apparatus, represented by an upper electrode and a lower electrode of CVD apparatuses is subjected to a plasma treatment while bearing static electricity, the electricity locally concentrates at a micro defect or another electrically weak portion in the member, and this may cause problems such as abnormal discharge.

The present invention has been made under such circumstances, and an object of the present invention is to provide a member for a plasma treatment apparatus, which excels in anti-sticking properties, has a stable shape suitable as a workpiece-supporting member such as a lower electrode of a CVD apparatus, and less suffers abnormal discharge during plasma treatment.

### Solution to Problem

To solve the problems, the present invention provides a member for constituting a plasma treatment apparatus which applies a plasma treatment to a workpiece, the member comprising a base material composed of aluminum or an aluminum alloy; and an anodic oxide coating present on a surface of the base material, in which the anodic oxide coating has a leak current density of more than 0.9×10⁻⁵ A/cm² at an applied voltage of 100 V, has a thickness of 3 μm or more, and has an arithmetic average surface roughness of less than 1 μm, and the surface on which the anodic oxide coating is present has a flatness of 50 μm or less.

According to the configuration, the anodic oxide coating formed on a surface of the base material has a predetermined thickness and thereby imparts corrosion resistance to the member for a plasma treatment apparatus. The anodic oxide coating has a leak current density of more than the predetermined level, whereby the member for a plasma treatment apparatus is charged with a less electric charge during plasma treatment, and this suppresses the electrostatic adsorption of the workpiece to the member for a plasma treatment apparatus serving as the lower electrode. Simultaneously this allows the member to have a uniformly distributed electric charge to thereby have a less amount of electrically concentrated portions. In addition, the anodic oxide coating has a smooth surface, namely, the member for a plasma treatment apparatus has a smooth surface, and this allows uniform and stable film deposition.

The anodic oxide coating preferably has a dissolution rate of less than 100 mg/dm² per 15 minutes in a chromic-phosphoric solution immersion test.

The dissolution rate as determined in the chromic-phosphoric solution immersion test demonstrates whether or not the anodic oxide coating is hydrated, and at least part of the coating is converted into boehmite and/or pseudoboehmite. Control of the hydration allows the formation of microcracks in the anodic oxide coating and thereby allows the control of the leak current density.

The arithmetic average surface roughness is preferably an arithmetic average surface roughness in a radial direction of the member for a plasma treatment apparatus.

Control of the arithmetic average surface roughness, a surface roughness measured along the radial direction of the member for a plasma treatment apparatus, in the above manner allows the resulting lower electrode to perform uniform film deposition.

The surface on which the anodic oxide coating is present preferably has a shape whose altitudinal position varies concentrically.

When the member for a plasma treatment apparatus has such a concentrically convex or concave surface whose altitudinal position varies concentrically from its center in the above manner, the member may be suitable as a lower electrode on which the workpiece can be mounted stably.

The present invention also provides a method for producing a member for a plasma treatment apparatus, which is a method for producing the member for a plasma treatment apparatus of any one of claims 1 to 4 and includes, in the following order, the steps of surface processing (mechanical cutting), anodizing, and hydrating.

The production method gives a member for a plasma treatment apparatus which includes an anodic oxide coating having a smooth surface and bears microcracks.

### Advantageous Effects of Invention

The member for a plasma treatment apparatus according to the present invention has satisfactory corrosion resistance and anti-sticking properties, less suffers abnormal discharge, and allows uniform and stable film deposition. The member for a plasma treatment apparatus according to claim 2 allows easy control of the leak current density of the anodic oxide coating, thereby has further improved anti-sticking properties, and further less suffers the abnormal discharge.

The member for a plasma treatment apparatus according to the present invention can have a surface shape suitable as a lower electrode of a CVD apparatus.

The method for producing a member for a plasma treatment apparatus according to the present invention allows easy production of the member for a plasma treatment apparatus.

### BRIEF DESCRIPTION OF DRAWINGS

FIG. 1 is a cross-sectional view schematically illustrating the structure of a member for a plasma treatment apparatus according to the present invention.

FIG. 2 are schematic cross-sectional views illustrating surface shapes of the member for a plasma treatment apparatus according to the present invention.

### REFERENCE SIGNS LIST

1 member for plasma treatment apparatus
2 base material
3 anodic oxide coating
31 barrier layer
32 porous layer
4 pore
5 cell

### BEST MODES FOR CARRYING OUT THE INVENTION

The configuration of the member for a plasma treatment apparatus according to the present invention will be described below.

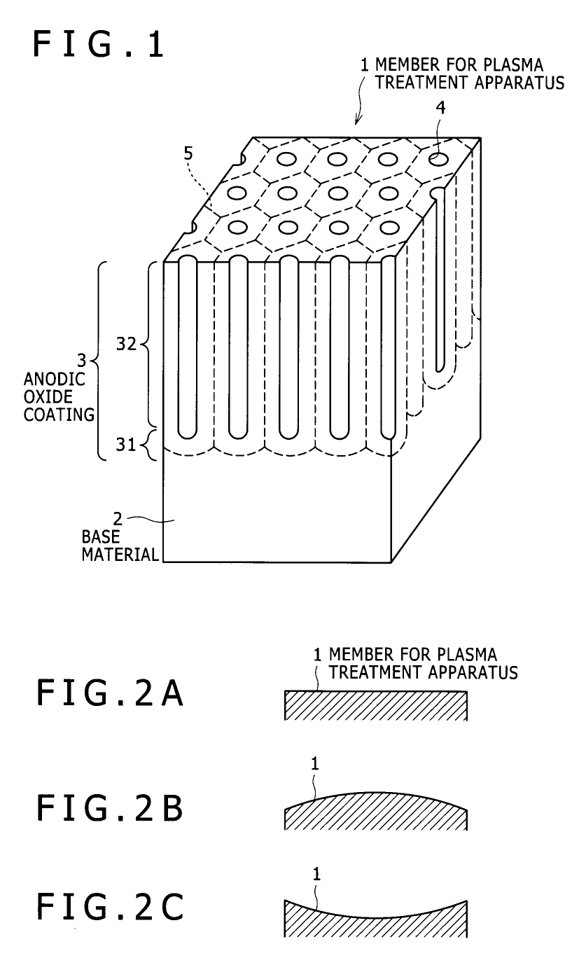

FIG. 1 is an enlarged schematic view of part of a member for a plasma treatment apparatus as an embodiment of the present invention; and FIG. 2 are schematic cross-sectional views illustrating surface shapes of members for a plasma treatment apparatus as embodiments of the present invention. With reference to FIG. 1, the member 1 for a plasma treatment apparatus includes a base material 2 composed of aluminum or an aluminum alloy; and an anodic oxide coating 3 present on a surface of the base material 2. Components constituting the member for a plasma treatment apparatus according to the present invention will be described below.

### [Base Material]

Though not limited, the aluminum or aluminum alloy constituting the base material 2 is preferably any of 3000 (Al—Mn) series alloys, 5000 (Al—Mg) series alloys, and 6000 (Al—Mg—Si) series alloys specified in Japanese Industrial Standards (JIS), because these alloys have satisfactory mechanical strength, thermal conductivity, and electrical conductivity as members for a plasma treatment apparatus. Though depending on the intended use of the member 1 for a plasma treatment apparatus, the base material 2 has been preferably processed into a rolled material, extruded material, or forged material. The processing may be performed according to a known procedure.

### [Anodic Oxide Coating]

The anodic oxide coating 3 is a cell assembly mainly composed of hexagonal prismatic cells 5 as unit cells. Each cell 5 has a pore (vacancy) 4 longitudinally or vertically extending at the center thereof. The anodic oxide coating 3 is a composite film including a porous layer 32 bearing the pores 4; and a barrier layer 31 which is positioned between the porous layer 32 and the base material 2 and bears no pore 4. The presence of the anodic oxide coating 3 on the surface of the base material 2 imparts corrosion resistance to the member 1 for a plasma treatment apparatus according to the present invention. The “surface of the base material 2” is not necessarily the whole surface but may be part of the surface of the base material in some intended uses of the member 1 for a plasma treatment apparatus. Typically, when the member is used as a lower electrode in a CVD apparatus, the anodic oxide coating 3 has only to be arranged on a surface of the base material on which the workpiece is to be mounted. In a preferred embodiment, the anodic oxide coating 3 is present further in portions to be in contact with the plasma and source gas. In another preferred embodiment, the surface (including side walls of the pores 4) of the anodic oxide coating 3 is converted into boehmite and/or pseudoboehmite, and thereby the anodic oxide coating 3 bears uniform microcracks.

(Leak Current Density at Applied Voltage of 100 V: More than 0.9×10⁻⁵ A/cm²)

According to the present invention, by allowing the anodic oxide coating 3 to generate a suitable leak current, the member 1 for a plasma treatment apparatus is charged with a less electric charge during plasma treatment. The member 1 for a plasma treatment apparatus, when used as a lower electrode in a CVD apparatus, helps to suppress the electrostatic adsorption of the workpiece. In addition, the member 1 for a plasma treatment apparatus has a uniformly distributed electric charge and thereby has a reduced amount of electrically concentrated portions. Thus, abnormal discharge during plasma treatment is suppressed. This is also true for the case where the member is also used as another member than the lower electrode. An anodic oxide coating having a leak current density of 0.9×10⁻⁵ A/cm² or less at an applied voltage of 100 V does not sufficiently show these advantageous effects. Accordingly, the anodic oxide coating should have a leak current density of more than 0.9×10⁻⁵ A/cm². The upper limit of the leak current density is not critical from the viewpoint of anti-sticking properties. However, the anodic oxide coating, if having a leak current density of more than 20×10⁻⁵ A/cm², may suffer such large cracks as to extend and penetrate the coating in a thickness direction and may cause the member to have insufficient corrosion resistance. For this reason, the anodic oxide coating 3 preferably has a leak current density of more than 0.9×10⁻⁵ A/cm² and 20×10⁻⁵ A/cm² or less at an applied voltage of 100 V. The leak current density of the anodic oxide coating 3 may be controlled by the thickness and structure of the coating, details of which will be described later.

### (Anodic Oxide Coating Thickness: 3 μm or More)

The anodic oxide coating 3 ensures the corrosion resistance of the member 1 for a plasma treatment apparatus, suppresses the quantity of, and uniformize the distribution of, the electric charge of the member during plasma treatment. An anodic oxide coating having a thickness of less than 3 μm may fail to ensure corrosion resistance including resistance to chemicals such as acids and bases, and resistance to gaseous corrosion. For this reason, the anodic oxide coating 3 has a thickness of 3 μm or more. The anodic oxide coating 3, if having a thickness of more than 120 μm, may become susceptible to peeling off due typically to internal stress. Accordingly, the anodic oxide coating 3 has a thickness of preferably 3 to 120 μm, and more preferably 10 to 70 μm.

The leak current density of the anodic oxide coating 3 may be controlled by the film thickness and structure. When the leak current density is intended to be controlled to more than 0.9×10⁻⁵ A/cm² by the film thickness alone, the film thickness should be less than 10 μm. In other words, when the anodic oxide coating 3 has a thickness of 10 μm or more, its structure should be controlled to attain such a suitable leak current density. However, it is preferred to control the structure of the anodic oxide coating 3 regardless of its thickness, in addition to the control of the thickness as to ensure satisfactory corrosion resistance. This is because, even when the anodic oxide coating has a thickness of less than 10 μm, the film should be controlled in its structure in order to have a more stable leak current density and to show further satisfactory corrosion resistance.

The structure control of the anodic oxide coating 3 for use in the present invention is the formation of microcracks in the anodic oxide coating 3 to generate a suitable leak current and to have satisfactory corrosion resistance simultaneously. The cracks discharge the electric charge which has been charged in the member 1 for a plasma treatment apparatus during plasma treatment, whereby the member bears a less quantity of electric charge. If the cracks are unevenly distributed in the anodic oxide coating 3, the electric charge in the member during plasma treatment does not distribute uniformly, whereby the member 1 for a plasma treatment apparatus has electrically concentrated portions to cause abnormal discharge. If the cracks are large and/or extend and penetrate the coating in a thickness direction of the anodic oxide coating 3, a gas may invade through the cracks to often cause the corrosion of the base material 2, resulting in insufficient corrosion resistance of the member. To avoid these problems, fine and uniformly dispersed cracks are preferably formed in the anodic oxide coating 3, which cracks do not to extend and penetrate the coating in a thickness direction. As cracks are formed by hydration and expansion of the anodic oxide coating 3, the preferred cracks are formed by controlling the hydration conditions of the anodic oxide coating 3 as mentioned later. The hydration allows at least part of the anodic oxide coating 3 to be converted into boehmite and/or pseudoboehmite.

(Anodic Oxide Coating Surface Roughness: Less than 1 μm)

The surface of the anodic oxide coating 3, namely, the surface of the member 1 for a plasma treatment apparatus is preferably as smooth as possible. If a member having an arithmetic average surface roughness Ra of 1 μm or more is used as a lower electrode in a CVD apparatus, it may cause uneven film deposition along the unevenness pattern on the workpiece. To avoid this, the anodic oxide coating 3 has an arithmetic average surface roughness Ra of less than 1 μm, and preferably less than 0.8 μm. The arithmetic average surface roughness Ra is preferably determined based on a surface roughness measured along the radius of the member 1 for a plasma treatment apparatus. The “arithmetic average surface roughness Ra” is prescribed in Japanese Industrial Standards (JIS) B0601. The control of the surface roughness may be performed on the aluminum or an aluminum alloy as the base material 2 prior to anodization and is preferably performed through machining to prevent warping of the member 1 for a plasma treatment apparatus. After the machining, the surface of the base material may be ground typically with a sand paper or through buffing.

(Dissolution Rate in Chromic-Phosphoric Solution Immersion Test: Less than 100 mg/dm² Per 15 Minutes)

The chromic-phosphoric solution immersion test according to JIS H8683-2 is one of test standards regarding the sealing of an anodic oxide coating applied to aluminum or an aluminum alloy, in which the sealing is determined based on the acid resistance of the anodic oxide coating. The test herein is performed to determine whether or not the surface of the anodic oxide coating 3 (including side walls of the pores 4) is converted into boehmite and/or pseudoboehmite. Specifically, when the anodic oxide coating has a dissolution rate of less than 100 mg/dm² per 15 minutes in the chromic-phosphoric solution immersion test, it demonstrates that at least part of the anodic oxide coating 3 is converted into boehmite and/or pseudoboehmite, and that a hydration reaction occurs to form cracks in the anodic oxide coating 3.

The parameters regarding the surface shape of the member for a plasma treatment apparatus according to the present invention will be described below.

### (Flatness: 50 μm or Less)

When the member 1 for a plasma treatment apparatus is used in a CVD apparatus as a lower electrode or another member on which the workpiece is mounted, the surface of the member, i.e., the surface of the anodic oxide coating 3 serves as a workpiece-mounting surface. This surface is preferably as flat as possible, for providing higher stability of the workpiece during plasma treatment and for ensuring uniformity of the plasma treatment such as film deposition. If the member 1 for a plasma treatment apparatus has a flatness of more than 50 μm, namely, has large unevenness of its surface, the workpiece mounted thereon may become unstable, or space may be left between the workpiece and the member 1 for a plasma treatment apparatus, thus causing uneven film deposition on the workpiece. To avoid these, the surface of the member 1 for a plasma treatment apparatus constituted by the anodic oxide coating 3 should have a flatness of 50 μm or less. Independently, if the member 1 for a plasma treatment apparatus has a wavy surface, space may be left between the member and the workpiece, thus causing uneven film deposition on the workpiece. If the surface shape, i.e., the altitudinal position of the surface varies not concentrically but disproportionately, the workpiece may not be mounted stably, thus causing uneven film deposition. To avoid these, the member 1 for a plasma treatment apparatus preferably has a convex surface (see FIG. 2(b)) or a concave surface (see FIG. 2(c)) whose altitudinal position gradually and concentrically increases or decreases from the center to the periphery. The surface is more preferably a concave surface. Specifically, the member 1 for a plasma treatment apparatus preferably has a conical or partial spherical surface without undulating or twisting. An ideal member 1 for a plasma treatment apparatus has a surface with a flatness of zero, i.e., a perfectly flat surface (see FIG. 2(a)). The member, when having a flatness of not zero, preferably has the above-mentioned surface shape so as to mount the workpiece horizontally without inclination. The processing of the surface shape is performed on the base material 2 before anodization, as in the control of the surface roughness of the anodic oxide coating 3.

Anodization and hydration processes for the formation of the anodic oxide coating for use in the present invention will be illustrated below.

### (Anodization)

Anodization is an electrolysis process in which aluminum (or aluminum alloy) to be the base material 2 is immersed in an electrolyte, a voltage is applied thereto, and thereby an aluminum oxide (Al₂O₃) film is formed on the surface of the aluminum by the action of oxygen generated at the anode. The voltage is applied in the anodization according to a known process such as a direct current process, an alternating current process, and a process of superimposed direct current on alternating current. Though not limited, examples of the electrolyte to be used in anodization herein include inorganic acid solutions such as sulfuric acid solutions, phosphoric acid solutions, chromic acid solutions, and boric acid solutions; organic acid solutions such as formic acid solutions and oxalic acid solutions; and mixtures of these solutions. The anodization temperature (electrolyte temperature) may be appropriately controlled according typically to the type and concentration of the electrolyte.

The anodization in the present invention may be performed through whichever of general voltage control and current control. The applied voltage in anodization is not critical. However, an excessively low electrolysis voltage causes an excessively low film growth rate, resulting in not so efficient anodic oxidization. In this case, the resulting anodic oxide coating may have insufficient hardness typically when an oxalic acid solution is used as the electrolyte. In contrast, an excessively high electrolysis voltage may cause the anodic oxide coating to be susceptible to dissolution, resulting in defects in the anodic oxide coating 3. Accordingly, the applied voltage may be appropriately controlled in consideration of these circumstances according typically to the film growth rate and the concentration of electrolyte. The process time of anodization is not critical and may be set so as to provide a time for the anodic oxide coating 3 to have a desired film thickness.

### (Hydration)

As is described above, the structure control of the anodic oxide coating 3 in the present invention is the formation of fine and uniform cracks in the anodic oxide coating 3. This is achieved by hydration (hydrating) in which the anodic oxide coating 3 expands as a result of a hydration reaction. Hydration is performed by bringing the work (anodic oxide coating) into contact with water at an elevated temperature, such as hot water immersion of immersing the work in hot water, and exposing the work to water vapor (steam). The “work” herein refers to the anodic oxide coating formed through the anodization and particularly refers to the porous layer. However, if the anodic oxide coating 3 undergoes excessive expansion in the vicinity of its surface, this may cause cracks to extend and penetrate the coating in a thickness direction. To avoid this, the hydration conditions, such as process temperature (temperature of the hot water or steam) and process time, should be finely controlled.

Next, an embodiment of the production method for the member for a plasma treatment apparatus according to the present invention will be illustrated below. Initially, aluminum or an aluminum alloy to be a base material 2 is processed according to a known procedure so as to give a desired shape of the member 1 for a plasma treatment apparatus. The surface of the aluminum or aluminum alloy (surface on which the anodic oxide coating 3 is to be formed) is smoothened through machining to give a base material 2. The surface roughness and flatness of the base material 2 in this state substantially correspond to the surface roughness and flatness of the resulting member 1 for a plasma treatment apparatus, i.e., of the surface on which the anodic oxide coating 3 is present.

Next, the base material 2 is anodized to form an anodic oxide coating on the surface of the base material 2. The formed anodic oxide coating is hydrated to give an anodic oxide coating 3 for use in the present invention.

### EXAMPLES

The best mode for carrying out the present invention has been described above. The present invention will be illustrated in further detail with reference to some working examples to verify the advantageous effects of the present invention, in comparison to comparative examples which do not satisfy the conditions specified in the present invention. It should be noted, however, that these examples are never construed to limit the scope of the present invention.

### (Preparation of Specimens)

Each of aluminum alloys shown in Table 1 was formed into three specimens, i.e., a plate 5 mm thick, and specimens having shapes corresponding to an upper electrode and a lower electrode of a CVD apparatus, and the specimens were processed on surface shape to have a flatness of 50 μm or less, machined (cut) to control the surface roughness, and thereby yielded a series of base materials. The machining was performed using a numerically controlled lathe (NC lathe) with a commercially available diamond tip. As is shown in Table 1, base materials according to Comparative Examples 5 to 7 were prepared in which surface processing was performed through blasting with aluminum abrasive grains.

Next, the base materials were each connected to an anode, were then immersed in any of electrolytes of compositions at temperatures given in Table 1, and an electricity was applied to form a series of anodic oxide coatings having film thicknesses given in Table 1. The anodized base materials were hydrated by immersing in hot water and thereby yielded specimens. The temperature and immersion time of the hot water are shown in Table 1. Specimens according to Examples 14 and 15 and Comparative Examples 1 to 4 had not been subjected to hydration and are indicated by the symbol “-” in “Hydration conditions”.

Of the resulting specimens, the plate specimens 5 mm thick were cut to test samples 50 mm long and 50 mm wide and subjected to measurements of the leak current density and the dissolution rate in a chromic-phosphoric solution immersion test. Some other specimens were formed into lower electrodes (250 mm in diameter) of a CVD apparatus and subjected to measurements of the surface roughness and flatness. The other specimens were formed into upper electrodes (250 mm in diameter) of the CVD apparatus and were used in the CVD apparatus together with the above-prepared lower electrodes, so as to determine anti-sticking properties and suppression of abnormal discharge of the lower electrodes.

### (Measurement of Leak Current Density)

Aluminum was deposited to a thickness of about 1 μm on the surface of the anodic oxide coating of each test sample to give a test electrode of about 1-cm square. A direct-current voltage of 100 V was applied between the deposited aluminum film and the base material 2, and the leak current density at an applied voltage of 100 V was measured using a commercially available current/voltage meter. The measured results are shown in Table 1. The acceptance criterion for the leak current density was more than 0.9×10⁻⁵ A/cm².

### (Chromic-Phosphoric Solution Immersion Test)

The test was performed in accordance with JIS H8683-2 (1999). Initially, each test sample was subjected to a pretreatment by immersing in a nitric acid aqueous solution (500 mL/L, at 18° C. to 20° C.) for 10 minute, rinsed with deionized water, dried by warm air, and the mass of the resulting test sample was measured. The test sample was immersed in an aqueous solution of phosphoric acid and chromic anhydride for 15 minutes. The aqueous solution was a solution of 35 mL of phosphoric acid and 20 g of chromic anhydride in 1 L of deionized water. The test sample after immersion was rinsed sequentially in a water bath and with running water, further rinsed with deionized water, dried by warm air, and the mass thereof was measured. Based on the measured masses, the mass loss per unit area was determined, and the results are shown in Table 1. When a specimen showed a mass loss of less than 100 mg/dm², namely, has a dissolution rate of less than 100 mg/dm² per 15 minutes, it is demonstrated that at least part of the anodic oxide coating 3 has been converted into boehmite and/or pseudoboehmite by hydration.

### (Measurement of Surface Roughness)

The surface roughness was measured along the radius of the sample lower electrode using HANDYSURF E-35A supplied by TOKYO SEIMITSU CO., LTD. according to the measuring method prescribed in JIS B0601 to determine an arithmetic average surface roughness Ra. The measured data are shown in Table 1.

### (Measurement of Flatness)

The flatness was measured along the radius of the sample lower electrode using a three-dimensional coordinate measuring machine XYZAX PA-1500A supplied by TOKYO SEIMITSU CO., LTD. The measured data are shown in Table 1.

### (Evaluation of Anti-Sticking Properties)

For evaluating the anti-sticking properties, abnormal discharge, and film deposition uniformity, the specimens as a lower electrode and an upper electrode were set to a CVD apparatus, and chemical vapor depositions were performed on 100 plies of a silicon wafer (200 mm in diameter) as the workpiece. The chemical vapor deposition for evaluating the anti-sticking properties and that for evaluating abnormal discharge were performed simultaneously. In the CVD apparatus, the process chamber was cleaned with a source gas, the workpiece wafer was placed on the lower electrode, and the lower electrode together with the wafer were heated to temperatures of 300° C. to 380° C. In the process chamber held under reduced pressure of about 2 to 5 Torr (about 260 to 670 Pa), plasma was generated, and this plasma treatment gives a silicon oxide film about 500 nm thick deposited on the surface of the wafer.

The anti-sticking properties were evaluated by mounting the specimen as the lower electrode to the CVD apparatus, performing chemical vapor deposition on 100 plies of the wafer, and determining whether sticking occurred or not. The presence of sticking was detected by elevating four dowel pins arranged at every 90 degrees on the periphery of the lower electrode after the chemical vapor deposition, lifting the wafer from its backside, and visually observing whether the wafer was peeled off from the lower electrode without resistance. A specimen causing no sticking on all the 100 plies of the wafer was evaluated as having satisfactory anti-sticking properties (“∘”); and one causing sticking on one or more plies of the wafer was evaluated as having poor anti-sticking properties (“×”). The evaluated data are shown in Table 1.

### (Evaluation of Abnormal Discharge)

The abnormal discharge (suppression) was evaluated by mounting the specimen as the lower electrode to the CVD apparatus, performing chemical vapor deposition on 100 plies of the wafer, and determining whether abnormal discharge occurred or not. As the occurrence of abnormal discharge, whether a brown or black dot-like mark having a diameter of about 0.1 to 1 mm, as a discharge mark, was formed on the surface of the upper electrode was visually observed after the chemical vapor deposition was performed on the 100 plies of the wafer. A sample showing no dot-like mark was evaluated as having satisfactory suppression on abnormal discharge (“∘”); and one showing one or more dot-like marks was evaluated as having poor suppression on abnormal discharge (“×”). The evaluated data are shown in Table 1.

### (Evaluation of Film Deposition Uniformity)

The film deposition uniformity was evaluated by mounting the specimen as the lower electrode to the CVD apparatus, performing chemical vapor deposition on 100 plies of the wafer, and determining whether the wafer suffered from uneven film deposition or not. The presence of uneven film deposition was visually observed. A sample causing no uneven film deposition and allowing uniform film deposition on all the 100 plies of the wafer was evaluated as having satisfactory film deposition uniformity (“∘”); and one causing uneven film deposition on one or more plies of wafers was evaluated as having poor film deposition uniformity (“×”). The evaluated data are shown in Table 1.

TABLE 1

| | | Specimen preparation conditions | | | | | | | Measured data | | | | Evaluated data | | |
|---|---|---|---|---|---|---|---|---|---|---|---|---|---|---|---|
| | | | | | | | Hydration | | | Disso- | Sur- | | Anti- | Abnor- | Film |
| | | Base material | | Anodization conditions | | | conditions | | | lution | face | | stick- | mal dis- | deposi- |
| | | Mate- | Sur- | | Process | Coating | Process | Proc- | Leak | rate | rough- | | ing | charge | tion |
| | | rial | face | | temper- | thick- | temper- | ess | current | (mg/dm² | ness | Flat- | prop- | sup- | uni- |
| | | Al | proc- | Elec- | ature | ness | ature | time | density | per 15 | Ra | ness | er- | pres- | form- |
| No. | | alloy | essing | trolyte | (° C.) | (μm) | (° C.) | (min) | (A/cm²) | min) | (μm) | (μm) | ties | sion | ity |
| Ex- | 1 | 6061 | machin- | 15% | 0 | 40 | 100 | 45 | 1.7 × | 15 | 0.5 | 7 | ∘ | ∘ | ∘ |
| am- | | | ing | sulfuric | | | | | 10⁻⁵ | | | | | | |
| ples | | | | acid | | | | | | | | | | | |
| | 2 | 6061 | machin- | 15% | 0 | 40 | 90 | 30 | 1.5 × | 21 | 0.6 | 8 | ∘ | ∘ | ∘ |
| | | | ing | sulfuric | | | | | 10⁻⁵ | | | | | | |
| | | | | acid | | | | | | | | | | | |
| | 3 | 6061 | machin- | 15% | 0 | 20 | 100 | 30 | 3.6 × | 18 | 0.3 | 12 | ∘ | ∘ | ∘ |
| | | | ing | sulfuric | | | | | 10⁻⁵ | | | | | | |
| | | | | acid | | | | | | | | | | | |
| | 4 | 6061 | machin- | 18% | 2 | 35 | 100 | 30 | 2.0 × | 17 | 0.2 | 9 | ∘ | ∘ | ∘ |
| | | | ing | sulfuric | | | | | 10⁻⁵ | | | | | | |
| | | | | acid | | | | | | | | | | | |
| | 5 | 6061 | machin- | 18% | 2 | 35 | 80 | 20 | 1.4 × | 82 | 0.8 | 20 | ∘ | ∘ | ∘ |
| | | | ing | sulfuric | | | | | 10⁻⁵ | | | | | | |
| | | | | acid | | | | | | | | | | | |
| | 6 | 6061 | machin- | 20% | 5 | 30 | 100 | 45 | 2.5× | 10 | 0.9 | 12 | ∘ | ∘ | ∘ |
| | | | ing | sulfuric | | | | | 10⁻⁵ | | | | | | |
| | | | | acid | | | | | | | | | | | |
| | 7 | 6061 | machin- | 2% | 15 | 10 | 100 | 30 | 2.3 × | 3 | 0.5 | 6 | ∘ | ∘ | ∘ |
| | | | ing | oxalic | | | | | 10⁻⁵ | | | | | | |
| | | | | acid | | | | | | | | | | | |
| | 8 | 6061 | machin- | 3% | 15 | 20 | 90 | 15 | 1.7 × | 5 | 0.6 | 7 | ∘ | ∘ | ∘ |
| | | | ing | oxalic | | | | | 10⁻⁵ | | | | | | |
| | | | | acid | | | | | | | | | | | |
| | 9 | 6061 | machin- | 4% | 20 | 20 | 80 | 20 | 2.0 × | 5 | 0.1 | 25 | ∘ | ∘ | ∘ |
| | | | ing | oxalic | | | | | 10⁻⁵ | | | | | | |
| | | | | acid | | | | | | | | | | | |
| | 10 | 5052 | machin- | 15% | 0 | 40 | 100 | 45 | 3.0 × | 25 | 0.7 | 30 | ∘ | ∘ | ∘ |
| | | | ing | sulfuric | | | | | 10⁻⁵ | | | | | | |
| | | | | acid | | | | | | | | | | | |
| | 11 | 5052 | machin- | 15% | 0 | 40 | 90 | 30 | 2.5 × | 33 | 0.5 | 8 | ∘ | ∘ | ∘ |
| | | | ing | sulfuric | | | | | 10⁻⁵ | | | | | | |
| | | | | acid | | | | | | | | | | | |
| | 12 | 5052 | machin- | 3% | 15 | 20 | 80 | 15 | 2.3 × | 14 | 0.6 | 15 | ∘ | ∘ | ∘ |
| | | | ing | oxalic | | | | | 10⁻⁵ | | | | | | |
| | | | | acid | | | | | | | | | | | |
| | 13 | 5052 | machin- | 15% | 0 | 3 | 100 | 45 | 9.5 × | 18 | 0.4 | 5 | ∘ | ∘ | ∘ |
| | | | ing | sulfuric | | | | | 10⁻⁵ | | | | | | |
| | | | | acid | | | | | | | | | | | |
| | 14 | 6061 | machin- | 15% | 0 | 5 | — | — | 2.4 × | 420 | 0.4 | 6 | ∘ | ∘ | ∘ |
| | | | ing | sulfuric | | | | | 10⁻⁵ | | | | | | |
| | | | | acid | | | | | | | | | | | |
| | 15 | 6061 | machin- | 3% | 15 | 5 | — | — | 1.6 × | 160 | 0.5 | 6 | ∘ | ∘ | ∘ |
| | | | ing | oxalic | | | | | 10⁻⁵ | | | | | | |
| | | | | acid | | | | | | | | | | | |
| Com- | 1 | 6061 | machin- | 15% | 0 | 40 | — | — | 0.8 × | 465 | 0.6 | 8 | x | x | ∘ |
| par- | | | ing | sulfuric | | | | | 10⁻⁵ | | | | | | |
| ative | | | | acid | | | | | | | | | | | |
| Ex- | 2 | 6061 | machin- | 15% | 20 | 20 | — | — | 0.9 × | 433 | 0.5 | 15 | x | x | ∘ |
| am- | | | ing | sulfuric | | | | | 10⁻⁵ | | | | | | |
| ples | | | | acid | | | | | | | | | | | |
| | 3 | 6061 | machin- | 3% | 18 | 20 | — | — | 0.5 × | 163 | 0.2 | 7 | x | x | ∘ |
| | | | ing | oxalic | | | | | 10⁻⁵ | | | | | | |
| | | | | acid | | | | | | | | | | | |
| | 4 | 5052 | machin- | 3% | 18 | 20 | — | — | 0.6 × | 172 | 0.3 | 7 | x | x | ∘ |
| | | | ing | oxalic | | | | | 10⁻⁵ | | | | | | |
| | | | | acid | | | | | | | | | | | |
| | 5 | 6061 | blast- | 15% | 0 | 40 | 100 | 45 | 0.7 × | 16 | 3.5 | 60 | ∘ | ∘ | x |
| | | | ing | sulfuric | | | | | 10⁻⁵ | | | | | | |
| | | | | acid | | | | | | | | | | | |
| | 6 | 6061 | blast- | 15% | 0 | 40 | 100 | 45 | 0.5 × | 5 | 3.2 | 75 | ∘ | ∘ | x |
| | | | ing | sulfuric | | | | | 10⁻⁵ | | | | | | |
| | | | | acid | | | | | | | | | | | |
| | 7 | 6061 | blast- | 3% | 15 | 20 | 90 | 15 | 0.5 × | 20 | 1.5 | 56 | ∘ | ∘ | x |
| | | | ing | oxalic | | | | | 10⁻⁵ | | | | | | |
| | | | | acid | | | | | | | | | | | |

### (Evaluation of Surface Shape)

Members according to Examples 1 to 15 had been prepared while processing the surface of the substrate (base material) through machining, thereby had a surface roughness and a flatness within the ranges specified in the present invention, and had surfaces of a centrally-protruded convex shape (see FIG. 2(b)) or a centrally-depressed concave shape (see FIG. 2(c)). Accordingly, when the members for a plasma treatment apparatus were used as the lower electrode, and a chemical vapor deposition was performed, they allowed the wafers to have satisfactorily uniformly deposited films. In contrast, members according to Comparative Examples 5 to 7 had been prepared while processing the surface of the base material through blasting, thereby had rough surfaces with an arithmetic average surface roughness Ra of 1.5 to 3.5 μm, and showed insufficient flatness due to warping caused by residual stress after blasting. Accordingly, these members for a plasma treatment apparatus, when a chemical vapor deposition was performed using them as the lower electrode, caused some wafers to suffer uneven film deposition, indicating that they are not suitable as lower electrodes of CVD apparatuses.

### (Evaluation Based on Leak Current Density)

The members according to Examples 1 to 13 had undergone hydration on the anodic oxide coating and thereby showed a dissolution rate of less than 100 mg/dm² per 15 minutes in the chromic-phosphoric solution immersion test, because at least part of the anodic oxide coating had been converted into boehmite and/or pseudoboehmite. The hydration allowed the anodic oxide coating to have microcracks to thereby have a leak current density of more than 0.9×10⁻⁵ A/cm². The resulting members for a plasma treatment apparatus excelled in anti-sticking properties and in suppression of abnormal discharge. Independently, the members according to Examples 14 and 15 had been prepared without hydration, thereby had a dissolution rate of 100 mg/dm² or more per 15 minutes. However, they had a leak current density of more than 0.9×10⁻⁵ A/cm², because of having a small thickness of the anodic oxide coating of 5 μm. The resulting members for a plasma treatment apparatus also excelled in anti-sticking properties and less suffered abnormal discharge, as with the members which had undergone hydration. In contrast, the members according to Comparative Examples 1 to 4, which had been prepared without hydration as in Examples 14 and 15, had a thickness of the anodic oxide coating of 10 μm or more, thereby had a leak current density of 0.9×10⁻⁵ A/cm² or less, and were inferior in anti-sticking properties and in suppression of abnormal discharge, to the members according to Examples 1 to 15.

1. A member, comprising:
a base material comprising aluminum or an aluminum alloy; and
an anodic oxide coating present on a surface of the base material,
wherein the anodic oxide coating has a leak current density of more than 0.9×10⁻⁵ A/cm² at an applied voltage of 100 V,
wherein the anodic oxide coating has a thickness of 3 μm or more,
wherein the anodic oxide coating has an arithmetic average surface roughness of less than 1 μm,
wherein the surface on which the anodic oxide coating is present has a flatness of 50 μm or less, and
wherein the member is suitable for employment in a plasma treatment device wherein a plasma treatment is applied to a work piece.

2. The member of claim 1, wherein the anodic oxide coating has a dissolution rate of less than 100 mg/dm² per 15 minutes in a chromic-phosphoric solution immersion test.

3. The member of claim 1, wherein an arithmetic average surface roughness is an arithmetic average surface roughness in a radial direction of the member.

4. The member of claim 1, wherein the surface on which the anodic oxide coating is present has a shape whose altitudinal position varies concentrically.

5. A method for producing the member of claim 1, the method comprising, in the following order:
processing, a surface of the base material, to obtain a processed material;
anodizing the processed material, to obtain an anodized material; and
hydrating the anodized material to give the member.

6. The member of claim 5, wherein the processing comprises a mechanical cutting.

7. The member of claim 1, wherein a surface of the anodic oxide coating comprises at least one selected from the group consisting of boehmite and pseudoboehmite.

8. The member of claim 1, wherein the anodic oxide coating bears uniform microcracks.

9. The member of claim 1, wherein the anodic oxide coating has a leak current density of more than 0.9×10⁻⁵ A/cm² and 20×10⁻⁵ A/cm² or less at an applied voltage of 100 V.

10. The member of claim 1, wherein the anodic oxide coating has a thickness of 3 to 120 μm.

11. The member of claim 1, wherein the anodic oxide coating has a thickness of 10 to 70 μm.

12. The member of claim 1, wherein the anodic oxide coating has a thickness of 3 μm less than 10 μm.

13. The member of claim 1, wherein the anodic oxide coating has an arithmetic average surface roughness Ra of less than 1 μm.

14. The member of claim 1, wherein the anodic oxide coating has an arithmetic average surface roughness Ra of less than 0.8 μm.

15. The member of claim 1, having a flatness of 50 μm or less.

16. The member of claim 1, having a convex surface whose altitudinal position gradually and concentrically increases or decreases from the center to the periphery.

17. The member of claim 1, having a concave surface whose altitudinal position gradually and concentrically increases or decreases from the center to the periphery.

18. The member of claim 1, having a flatness above zero.

19. The member of claim 1, wherein the anodic oxide coating has an arithmetic average surface roughness Ra of less than 0.7 μm.

20. The member of claim 1, wherein the anodic oxide coating has an arithmetic average surface roughness Ra of less than 0.6 μm.
